(19) United States
(12) Patent Application Publication
(10) Pub. No.: US 2013/0181331 A1
(43) Pub. Date: Jul. 18, 2013

(54) ATMOSPHERIC-PRESSURE PLASMA-ENHANCED CHEMICAL VAPOR DEPOSITION

(71) Applicants: Guruvenket Srinivasan, Fargo, ND (US); Robert Sailer, West Fargo, ND (US)

(72) Inventors: Guruvenket Srinivasan, Fargo, ND (US); Robert Sailer, West Fargo, ND (US)

(73) Assignee: NDSU RESEARCH FOUNDATION, Fargo, ND (US)

(21) Appl. No.: 13/876,225

(22) PCT Filed: Sep. 28, 2011
(86) PCT No.: PCT/US11/53624

§ 371 Date: Mar. 27, 2013

Related U.S. Application Data
(60) Provisional application No. 61/387,256, filed on Sep. 28, 2010.

(51) Int. Cl. H01L 31/0216; H01L 21/02

(52) U.S. Cl. CPC H01L 31/02168; H01L 21/02208
USPC 257/649; 438/793

(57) ABSTRACT

Provided are silicon-containing films with a refractive index suitable for antireflection, articles having a surface comprising the films, and atmospheric-pressure plasma-enhanced chemical vapor deposition (AE-PECVD) processes for the formation of surface films and coatings. The processes generally include providing a substrate, providing a precursor comprising silicon, and reacting the precursor with a gas comprising nitrogen (N2) in a low-temperature plasma at atmospheric pressure, wherein the products of the reacting form a film on the substrate. An antireflection coating made by the process can have a refractive index of about 1.5 to about 2.2. Articles are provided having a surface that includes the antireflection coating.

### CROSS-REFERENCE TO RELATED APPLICATIONS

This application claims the benefit of priority to U.S. Provisional Patent Application No. 61/387,256, filed Sep. 28, 2010, the content of which is incorporated herein by reference in its entirety.

### FEDERALLY-SPONSORED RESEARCH AND DEVELOPMENT

Activities relating to the development of the subject matter of this invention were funded at least in part by the U.S. Government, Department of Energy Grant Nos. DOE-PV-DS-43500 and DE-FC36-08G088160. The United States Government has certain rights in this invention.

### BACKGROUND

Smooth silicon surfaces can reflect about 35% of incident light, which can cause losses in solar cells made of the silicon. Wu Meiling, Z. W., Zhang Xinqiang, Liu Hao, Jia Shiliang & Qiu Nan, Study on the SiN Anti-Reflective Coating for Nanocrystalline Silicon Solar Cells, in PROCEEDINGS OF ISES WORLD CONGRESS 2007, 1234-38 (D. Yogi Goswami & Yuwen Zhao eds., 2007) (incorporated by reference herein). To reduce the optical losses due to reflection, the surface is typically textured or covered by an antireflection coating (ARC). Single-layer ARC, double-layer ARC, or triple-layer ARC with tuned refractive indices and thickness can provide antireflection properties ranging from 10% to 0.8% over a broad band of wavelengths depending on the dielectric material combinations used. M. Lipiński & R. Mroczyński, Optimisation of Multilayers Antireflection Coating for Solar Cells, 53(1) ARCHIVES OF METALLURGY AND MATERIALS 189-92 (incorporated by reference herein); D. Bouhafs, A. Moussi, A. Chikouche & J. M. Ruiz, Design and simulation of antireflection coating systems for optoelectronic devices: Application to silicon solar cells, 52(1-2) SOLAR ENERGY MATERIALS AND SOLAR CELLS 79-93 (1998) (incorporated by reference herein). Of the various coatings, the single-layer ARC can be most simple in processing and therefore suitable for photovoltaic applications such as solar cells.

Coatings of amorphous silicon carbide (a-SiC:H), amorphous silicon nitride (a-SiN:H), and amorphous silicon carbonitride (a-SiCN:H) can be used as a single-layer ARC in photovoltaic applications. See generally M. H. Kang, D. S. Kim, A. Ebong, B. Rounsaville, A. Rohatgi, G. Okoniewska & J. Hong, The Study of Silane-Free SiCₓN_{y} Film for Crystalline Silicon Solar Cells, 156(6) JOURNAL OF THE ELECTROCHEMICAL SOC'Y H495-H499 (2009) (incorporated by reference herein). Suitable coatings are typically manufactured by vacuum-based methods such as physical vapor deposition (PVD), chemical vapor deposition (CVD), or plasma-enhanced chemical vapor deposition (PECVD). See generally K. C. Mohite, Y. B. Khollamb, A. B. Mandaleb, K. R. Patilb & M. G. Takwale, Characterization of silicon oxynitride thin films deposited by electron beam physical vapor deposition technique, 57(26-27) MATERIALS LETTERS 4170-75 (2003) (incorporated by reference herein); J. Dupuis, E. Fourmond, J. F. Lelièvre, D. Ballutaud & M. Lemiti, Impact of PECVD SiON stoichiometry and post-annealing on the silicon surface passivation, 516(20) THIN SOLID FILMS 6954-58 (2008) (incorporated by reference herein); V. Verlaan, C. H. M. van der Werf, Z. S. Houweling, I. G. Romijn, A. W. Weeber, H. F. W. Dekkers, H. D. Goldbach & R. E. I. Schropp, Multi-crystalline Si solar cells with very fast deposited (180 nm/min) passivating hot-wire CVD silicon nitride as antireflection coating, 15(7) PROGRESS IN PHOTOVOLTAICS: RESEARCH AND APPLICATIONS 563-573 (2007) (incorporated by reference herein); F. X. Lu, H. B. Guo, S. B. Guo, Q. He, C. M. Li, W. Z. Tang & G. C. Chen, Magnetron sputtered oxidation resistant and antireflection protective coatings for freestanding diamond film IR windows, 18(2-3) DIAMOND AND RELATED MATERIALS 244-48 (2009) (incorporated by reference herein); Sumita Mukhopadhyay, Tapati Jana & Swati Ray, Development of low temperature silicon oxide thin films by photo-CVD for surface passivation, 23 J. VAC. SCI. TECHNOL. A 417 (2005) (incorporated by reference herein). The vacuum-based methods typically require temperatures above about 600° C., and the coating is deposited using pyrophoric and toxic chemicals such as monosilanes, disilanes, trisilanes, and ammonia.

### SUMMARY

In one aspect, the disclosure provides a process for forming a silicon-containing film on a substrate, the process comprising providing a substrate, providing a precursor comprising silicon, and reacting the precursor with a gas comprising nitrogen (N₂) in a low-temperature plasma at atmospheric pressure, wherein the products of the reacting form a film on the substrate.

In another aspect, the disclosure provides an antireflection coating made by a process comprising reacting a silicon-containing precursor with a gas comprising nitrogen (N₂) in a low-temperature plasma at atmospheric pressure wherein the antireflection coating has a refractive index of about 1.5 to about 2.2.

In another aspect, the disclosure provides an article having a surface comprising an antireflection coating, wherein the coating may be made by a process comprising reacting a silicon-containing precursor with a gas comprising nitrogen (N₂) in a low-temperature plasma at atmospheric pressure, wherein the coating has a refractive index of about 1.5 to about 2.2.

Other aspects and embodiments are encompassed within the scope of the disclosure and will become apparent in light of the following description and accompanying Drawings.

### BRIEF DESCRIPTION OF THE DRAWINGS

FIG. 1 schematically illustrates a non-limiting embodiment of an atmospheric-pressure plasma-enhanced chemical vapor deposition (AP-PECVD) process falling within the scope of the disclosure.

FIG. 2 is a graph plotting Fourier transform infrared (FTIR) spectroscopy spectra of silicon-based thin films deposited by non-limiting AP-PECVD embodiments falling within the scope of the disclosure as described herein, including, for example, FIG. 1.

FIG. 3 is a graph plotting a refractive index as a function of a substrate temperature for a-SiCN:H coatings manufactured by non-limiting AP-PECVD embodiments falling within the scope of the disclosure as described herein, including, for example, FIG. 1.

FIG. 4 is a graph plotting mechanical properties as a function of a substrate temperature for amorphous silicon carbonitride (a-SiCN:H) coatings manufactured by non-limiting AP-PECVD embodiments falling within the scope of the disclosure as described herein, including, for example, FIG. 1.

FIG. 5 is a graph plotting specular reflectance measured on a-SiCN:H coatings manufactured by non-limiting AP-PECVD embodiments falling within the scope of the disclosure as described herein, including, for example, FIG. 1.

FIG. 6 is a graph plotting FTIR spectra of a-SiN:H films for antireflection coating manufactured by non-limiting AP-PECVD embodiments falling within the scope of the disclosure as described herein, the AP-PECVD using a cyclohexasilane precursor.

FIG. 7 is a graph plotting surface roughness as a function of substrate temperature for antireflection coating manufactured by non-limiting AP-PECVD embodiments falling within the scope of the disclosure as described herein, the AP-PECVD using a cyclohexasilane precursor.

FIG. 8 is a graph plotting hardness as a function of substrate temperature for antireflection coating manufactured by non-limiting AP-PECVD embodiments falling within the scope of the disclosure as described herein, the AP-PECVD using a cyclohexasilane precursor.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

It also is specifically understood that any numerical value recited herein includes all values from the lower value to the upper value, i.e., all possible combinations of numerical values between the lowest value and the highest value enumerated are to be considered to be expressly stated in this application. For example, if a concentration range or a beneficial effect range is stated as 1% to 50%, it is intended that values such as 2% to 40%, 10% to 30%, or 1% to 3%, etc. are expressly enumerated in this specification. These are only examples of what is specifically intended.

Further, no admission is made that any reference, including any patent or patent document, cited in this specification constitutes prior art. In particular, it will be understood that, unless otherwise stated, reference to any document herein does not constitute an admission that any of these documents forms part of the common general knowledge in the art in the United States or in any other country. Any discussion of the references states what their authors assert, and the applicant reserves the right to challenge the accuracy and pertinence of any of the documents cited herein.

In a general sense, the disclosure relates to silicon-containing films with a refractive index suitable for antireflection, articles having a surface comprising the films, and atmospheric-pressure plasma-enhanced chemical vapor deposition (AE-PECVD) processes for the formation of surface films and coatings. The methods provided herein have advantages over known vacuum-based deposition methods that typically require large, expensive equipment with substantial operation and maintenance costs. See generally M. H. Kang, D. S. Kim, A. Ebong, B. Rounsaville, A. Rohatgi, G. Okoniewska & J. Hong, The Study of Silane-Free SiCxNy Film for Crystalline Silicon Solar Cells, 156(6) JOURNAL OF THE ELECTROCHEMICAL SOC'Y H495-H499 (2009) (incorporated by reference herein). Existing vacuum methods typically use instrumentation that can be complicated because of requirements for cooling and heat-shielding and typically produce films and coatings that are prone to wafer damage during manipulation, and can be limited in deposition rates and difficult to scale up. See generally M. L. Hitchman, Editorial: Atmospheric Pressure Plasma Enhanced CVD, 11(11-12) CHEM. VAPOR DEPOSITION 455 (2005) (incorporated by reference herein). Furthermore, handling and waste mitigation of toxic byproducts produced by these processes can add to the already high production cost. The AE-PECVD processes that are described herein can substantially decrease the overall costs of production.

Similarly, processes employing atmospheric-pressure plasma have been used in surface cleaning and plasma polymerization, for example as a dielectric barrier discharge (Dow-corning), atmospheric-pressure plasma jet (see generally A. Schutze, J. Y. Jeong, S. E. Babayan, Jaeyoung Park; G. S. Selwyn & R. F. Hicks, The atmospheric-pressure plasma jet: a review and comparison to other plasma sources, 26(6) IEEE TRANSACTIONS ON PLASMA SCIENCE 1685-94 (1998) (incorporated by reference herein)), and hollow cathode discharge (see generally Hana Baránkováa & Ladislav Bardos, Hollow cathode and hybrid plasma processing, 80(7) VACUUM 688-92 (2006) (incorporated by reference herein)).

Atmospheric-pressure plasma methods also have utility in forming functional thin films. See, e.g., M. L. Hitchman, supra; Robert A. Sailer, Andrew Wagner, Chris Schmit, Natalie Klaverkamp & Douglas L. Schulz, Deposition of transparent conductive indium oxide by atmospheric-pressure plasma jet, 203(5-7) SURFACE AND COATINGS TECH. 835-38 (2008) (incorporated by reference herein); M. Moravej & R. F. Hicks, Atmospheric Plasma Deposition of Coatings Using a Capacitive Discharge Source, 11(11-12) CHEM. VAPOR DEPOSITION 469-76 (2005) (incorporated by reference herein). In particular, coatings like SiOₓ and SiOC have been deposited using atmospheric-pressure plasma with suitable processing conditions of the precursor chemistry, plasma power, and substrate temperature. For example, SiOₓ thin films can be deposited using silicon-based precursors such as trimethylsilane and hexamethylydisiloxane (HMDSO) with and without carbon by suitably tuning the deposition parameters. With HMDSO at low flow rates, it is feasible to form inorganic SiO₂ films free from carbon via micro-plasma jet with inert gas plasma (without addition of reactive gas such as oxygen/ozone). V. Raballand, J. Benedikt & A. von Keudell, Deposition of carbon-free silicon dioxide from pure hexamethyldisiloxane using an atmospheric microplasma jet, 92 APPL. PHYS. LETT. 091502 (2008) (incorporated by reference herein); V. Raballand, J. Benedikt, S. Hoffmann, M. Zimmermann & A. von Keudell, Deposition of silicon dioxide films using an atmospheric pressure microplasma jet, 105 J. APPL. PHYS. 083304 (2009) (incorporated by reference herein). In contrast to known atmospheric-pressure plasma methods, non-limiting AP-PECVD embodiments falling within the scope of the disclosure as described herein are performed in an environment that is substantially free of oxygen.

A “PECVD” or “plasma-enhanced chemical vapor deposition” as used herein includes any process in which a reactive gas is introduced into the reaction vessel and a plasma is created by applying an electric field across the reactive and plasma gas. In contrast to an atmospheric-pressure PECVD, in a conventional PECVD process the reaction vessel is at a pressure lower than ambient pressure. The reaction vessel in a PECVD process can be evacuated by means of vacuum pumps.

“SiC,” “SiN,” and “SiCN” as used herein represent materials that contain the indicated elements in various proportions. For example, “SiCN” is a material that comprises silicon, carbon, nitrogen, and, optionally, other elements. “SiC,” “SiN,” and “SiCN” are not chemical stoichiometric formulae per se and thus are not limited to materials that contain particular ratios of the indicated elements. Furthermore, “silicon carbide,” “silicon nitride,” and “silicon carbonitride” as used herein include both stoichiometric, such as, for example, Si₃N₄ for silicon nitride, and non-stoichiometric type materials.

A “substrate” as used herein includes one or more materials that are able to, or adapted to, receive a film or coating layer and can include at least one surface layer(s) upon which film is to be formed, such as, for example, a semiconductor wafer substrate of silicon.

“Plasma conditions” and “deposition parameters” as used herein include pressure, temperature, reactive gas concentration, and any other standard parameter that may affect the film quality and properties.

A “reactive gas” or “reactant gas” as used herein refers to the gas or gases being deposited in the CVD process.

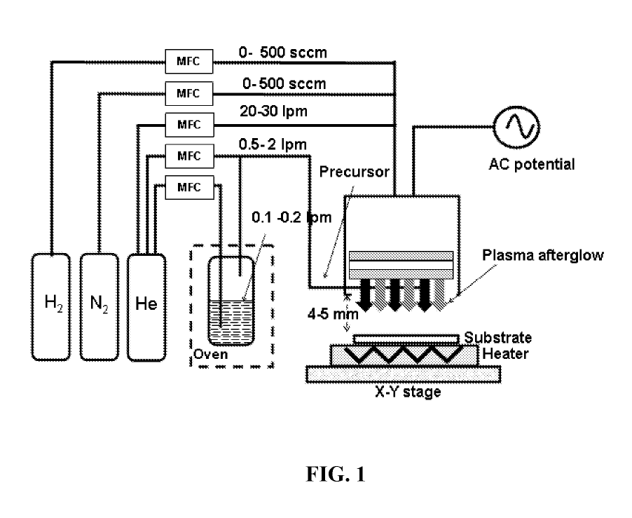

Referring to FIG. 1, in an aspect, the disclosure relates to a process for forming a silicon-containing film on a substrate, the process comprising providing a substrate, providing a precursor comprising silicon, and reacting the precursor with a gas comprising nitrogen (N₂) in a low-temperature plasma at atmospheric pressure, wherein the products of the reacting form a film on the substrate. Surprisingly, it was found that the introduction of nitrogen as reactive gas in AE-PECVD results in a nitride or carbonitride phase. The disclosed AE-PECVD process allows for the use of smaller and less complicated equipment compared to vacuum-based methods, rendering it amenable for scale-up and also allowing for cheaper operation. As described herein, non-limiting embodiments of the disclosed AE-PECVD process finds applicability in applications relating to the processing of antireflection coatings for use in, for example, silicon solar-cell manufacturing.

In general any compound having a formula Rₓ—Si, wherein R is selected from N-alkyl or C-alkyl, or any combination of alkyl groups, and x is an integer from selected from 1, 2, 3, or 4, can be used as the precursor for producing a silicon-based film, for example, silicon carbide, silicon nitride, silicon carbonitride, and the like, as described herein. In embodiments, the method comprises reacting or contacting a silicon-containing precursor in a plasma afterglow. In some embodiments, the silicon-containing precursor can comprise any suitable silane (Si—C) or silizane (Si—N) compound such as, for example, any branched or linear C1-C6 di-, tri-, or tetra-alkyl silane or silazane. Some non-limiting examples of such precursors include cyclohexasilane, dimethylsilane, trimethylsilane, tetramethylsilane, diethylsilane, triethylsilane (TES), tetraethylsilane, dipropylsilane, tripropylsilane, tetrapropylsilane, and the like. In some embodiments the precursors can include, for example, bis(tertiarybutylamino)silane, 1,1,3,3-tetramethyldisilazane, hexamethylcyclotrisilazane, tris(dimethylamino)methylsilane and bis(dimethylamino)methylsilane. In further embodiments precursor molecule can comprise one or more silicon-nitrogen (SiN) bonds (e.g., a silazane compound). In some embodiments, the precursor is liquid at room temperature. In further embodiments, the precursor is a volatile compound.

In some embodiments, the precursor is heated, for example in an oven, to a temperature of about 33° C. The temperature can be suitably higher or lower depending upon the precursor. For example, a cyclohexasilane precursor can be heated to about 55° C. to increase the vapor pressure. A carrier gas can be bubbled through the heated precursor to carry the heated precursor into a reaction vessel. The carrier gas can be helium, argon, nitrogen, or a combination thereof. In addition to the carrier gas, a reactive gas is flowed into the reaction vessel. The reactive gas includes nitrogen and optionally helium, argon, or hydrogen, ammonia, or a combination thereof. In embodiments, the reactive gas can include nitrogen in an amount of about 0.01% to about 100.00% and other optional gases (e.g., helium, argon, hydrogen) in an amount of 0.00% to about 99.99% by volume. In some embodiments, the reactive gas comprises nitrogen with 0% to about 5% hydrogen by volume. In some embodiments, the reactive gas can comprise about 45% or more, about 50% or more, about 55% or more, about 60% or more, about 65% or more, about 70% or more, about 75% or more, about 80% or more, about 82% or more, about 84% or more, about 86% or more, about 88% or more, about 90% or more, about 91% or more, about 92% or more, about 93% or more, about 94% or more, about 95% or more, about 96% or more, about 97% or more, about 98% or more, or about 99% or more by volume nitrogen. In some embodiments, the other optional gas comprises about 5% hydrogen by volume. In some embodiments, the reactive gas used in the disclosed method can be substantially free of ammonia. In other embodiments, the precursor includes cyclochexasilane and the reactive gas comprises ammonia. The reactive gas can comprise 0% to about 5% ammonia by volume.

In the reaction vessel, a substrate is awaiting the film deposition. In some embodiments, the substrate includes silicon. In further embodiments, the substrate is maintained at a temperature from about 25° C. to about 450° C. The substrate can be maintained at a temperature of about 25° C. or higher, about 50° C. or higher, about 75° C. or higher, about 100° C. or higher, about 125° C. or higher, about 150° C. or higher, about 175° C. or higher, about 200° C. or higher, about 225° C. or higher, about 250° C. or higher, about 275° C. or higher, about 300° C. or higher, about 325° C. or higher, about 350° C. or higher, about 375° C. or higher, about 400° C. or higher, about 425° C. or higher, or about 425° C. or higher. The substrate can be maintained at a temperature of about 450° C. or lower, about 425° C. or lower, about 400° C. or lower, about 375° C. or lower, about 325° C. or lower, about 300° C. or lower, about 275° C. or lower, about 250° C. or lower, about 225° C. or lower, about 200° C. or lower, about 175° C. or lower, about 150° C. or lower, about 125° C. or lower, about 100° C. or lower, about 75° C. or lower, or about 50° C. or lower. In some embodiments, the substrate can be maintained at a temperature of about 100° C. to about 450° C., about 200° C. to about 425° C., about 250° C. to about 425° C., or about 250° C. to about 350° C.

In order to deposit the film, an RF power or plasma power from about 40 W to about 150 W is applied to excite the plasma. In some embodiments, the plasma power is about 40 W or higher, about 50 W or higher, about 60 W or higher, about 70 W or higher, about 80 W or higher, about 90 W or higher, about 100 W or higher, about 110 W or higher, about 120 W or higher, about 130 W or higher, or about 140 W or higher. The plasma power can be about 150 W or lower, about 140 W or lower, about 130 W or lower, about 120 W or lower, about 110 W or lower, about 100 W or lower, about 90 W or lower, about 80 W or lower, about 70 W or lower, about 60 W or lower, or about 50 W or lower. In some embodiments, the plasma power is about 80 W to about 120 W, or about 110 W to about 130 W.

The disclosed method can be performed using any atmospheric-pressure plasma source with a low-temperature, or “non-thermal,” plasma. In some embodiments, the method can be performed using non-pyrophoric, non-toxic chemicals. The method can be performed in any suitable reaction vessel such as, for example, a glove box, a closed reactor or container, or in any environment that is substantially free of oxygen. In some embodiments, the reaction environment can, for example, be purged or shielded with nitrogen gas or argon in order to remove oxygen from the immediately surrounding atmosphere (e.g., a reaction environment that is free or substantially free of oxygen).

In another aspect, the disclosure relates to an antireflection coating made by a process comprising reacting a silicon-containing precursor with a gas comprising nitrogen (N₂) in a low-temperature plasma at atmospheric pressure wherein the antireflection coating has a refractive index of about 1.5 to about 2.2. In some embodiments, the antireflection coating has a refractive index of about 1.1 or more, about 1.2 or more, about 1.3 or more, about 1.4 or more, about 1.5 or more, about 1.6 or more, about 1.7 or more, about 1.8 or more, about 1.9 or more, about 2.0 or more, or about 2.1 or more. The refractive index can be about 2.2 or less, about 2.1 or less, about 2.0 or less, about 1.9 or less, about 1.8 or less, about 1.7 or less, about 1.6 or less, about 1.5 or less, about 1.4 or less, about 1.3 or less, or about 1.2 or less. In some embodiments, the antireflection coating has a refractive index of about 1.6 to about 1.9, about 1.9 to about 2.2, about 2.0 to about 2.2, about 1.6 to about 1.8, about 1.6 to about 1.7, or about 1.5 to about 1.7.

In some embodiments, the disclosure relates to anti-reflection coatings including at least one of silicon nitride and silicon carbonitride, or multilayers thereof. In further embodiments, the coatings are substantially free of silicon oxide. The coatings are manufactured by methods as described herein. The coatings can be further characterized by a hardness of about 7 GPa to about 17 GPa (e.g., about 7, about 8, about 9, about 10, about 11, about 12, about 13, about 14, about 15, about 16, or about 17 GPa). In some embodiments, the coating has a hardness of about 7 GPa or more, about 8 GPa or more, about 9 GPa or more, about 10 GPa or more, about 11 GPa or more, about 12 GPa or more, about 13 GPa or more, about 14 GPa or more, about 15 GPa or more, or about 16 GPa or more.

In another aspect, the disclosure provides an article having a surface comprising an antireflection coating, wherein the coating may be made by a process comprising reacting a silicon-containing precursor with a gas comprising nitrogen (N₂) in a low-temperature plasma at atmospheric pressure, wherein the coating has a refractive index of about 1.5 to about 2.2. Such articles include, but are not limited to, solar cells, protective coatings to prevent wear and corrosion, for example in opto electronic applications, and dielectric layers in microelectronics devices. The articles can also include windows and other applications that use panes of glass as substrates.

The present disclosure is illustrated by the following examples. It is to be understood that the particular examples, materials, amounts, and procedures are to be interpreted broadly in accordance with the scope and spirit of the invention as set forth herein.

### EXAMPLES

### Example 1

A low-temperature atmospheric-pressure plasma was used with non-pyrophoric chemicals to obtain silicon-based coatings having refractive indices suitable for an antireflection coating. An atmospheric pressure plasma system by Surfx Technologies (Culver City, Calif.) was used with a triethylsilane precursor procured from Gelest Inc. (Morrisville, Pa.). The precursor was reacted with a mixture of nitrogen and hydrogen gas, and deposited on a silicon substrate that was heated to a temperature from about 250° C. to about 450° C. The refractive indices of the resulting coating were from about 1.60 to about 1.87.

### Example 2

A low-temperature atmospheric-pressure plasma was used in the atmospheric pressure plasma system Atomflow™ 250D by Surfx Technologies (Culver City, Calif.) (see generally M. Moravej & R. F. Hicks, supra; M. D. Barankin, E. Gonzalez II, A. M. Ladwig & R. F. Hicks, Plasma-enhanced chemical vapor deposition of zinc oxide at atmospheric pressure and low temperature, 91(10) SOLAR ENERGY MATERIALS AND SOLAR CELLS 924-30 (2007)). The precursor used was triethylsilane (HSiEt3), [H—Si—(C₂H₅)₃] with a boiling point of about 117° C. to about 118° C. and vapor pressure of about 23 Torr at 20° C., procured from Gelest Inc. (Morrisville, Pa.). The plasma carrier gas included helium and nitrogen, and the reactive gas included nitrogen with or without 5% by volume of hydrogen.

The triethylsilane precursor was initially maintained in a heated bubbler at 33° C., bubbling helium gas through the triethylsilane precursor at 0.1 liter/minute. Subsequently, the triethylsilane precursor was delivered to the plasma source through delivery lines, which were maintained at 100° C. to preclude condensation. The substrate measured about 2.5 cm×2.5 cm and was maintained at a temperature from about 200° C. to about 425° C. The plasma head was held at 125° C., and at a distance of about 4 mm to about 5 mm from the substrate. Helium gas was supplied to the plasma source at about 20 liter/minute to about 30 liter/minute. Reactive gases included nitrogen with or without 5% by volume of hydrogen, at variable flow rates. Depositions were carried out by moving the heated substrate under the plasma source in a serpentine motion at a velocity of about 0.6×10⁻² m·s⁻¹. Suitable length, width, and step sizes were chosen to produce a uniform film deposition over the surface of the substrate.

To investigate the chemical bonding structure of the deposited films, Fourier transform infrared spectroscopy (FTIR) was performed with a Thermo Scientific Nicolet 8700 instrument. Spectroscopic ellipsometry was performed using an ellipsometer by J.A. Woollam Co. (Lincoln, Nebr.) to determine the film thickness, optical constant, and the reflectance. Spectroscopic ellipsometry was conducted at three different angles, namely, about 60°, about 67°, and about 74°. The measured ellipsometric parameters Ψ and Δ were fitted with the thin film model, where the thin film is assumed as Cauchy layer with silicon as the substrate. FTIR peaks were assigned based on reports available on similar coatings/precursors. See generally A. M. Wróbel, I. Blaszczyk-Lezak, A. Walkiewicz-Pietrzykowska, D. M. Bielinski, T. Aoki & Y. Hatanaka, Silicon Carbonitride Films by Remote Hydrogen-Nitrogen Plasma CVD from a Tetramethyldisilazane Source, 151(11) J. ELECTROCHEM. SOC'Y C723-30 (2004) (incorporated by reference herein); S. Guruvenket, M. Azzi, D. Li, J. A. Szpunar, L. Martinu & J. E. Klemberg-Sapieha, Structural, mechanical, tribological, and corrosion properties of a-SiC:H coatings prepared by PEC VD, 204(21-22) SURFACE AND COATINGS TECH. 3358-65 (2010) (incorporated by reference herein); S. Guruvenket, Jay Ghatak, P. V. Satyam & G. Mohan Rao, Characterization of bias magnetron-sputtered silicon nitride films, 478(1-2) THIN SOLID FILMS 256-60 (2005) (incorporated by reference herein).

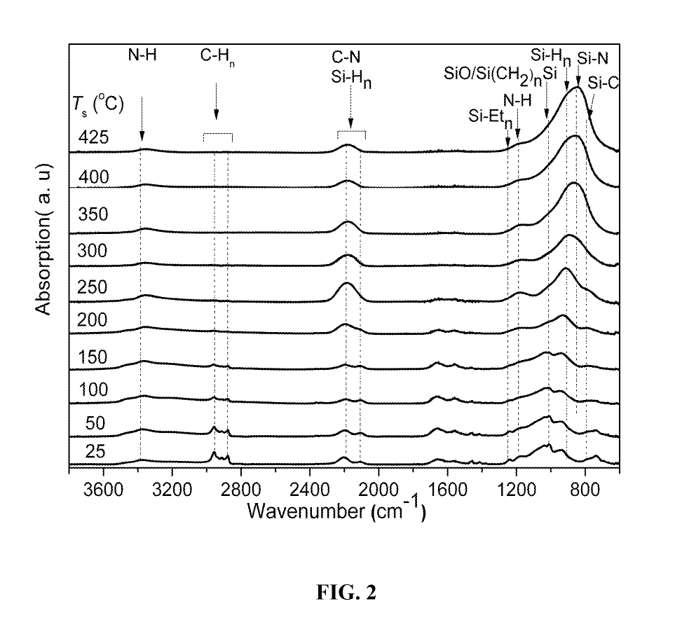

Referring to FIG. 2, the FTIR spectrum shows spectra of the deposited thin films. The films were deposited at about 25° C. to about 420° C. and a plasma power of about 100 W to about 140 W; The spectrum indicated that the film deposited below about 250° C. is primarily composed of Si—(CH)ₙ and NH bonds. Though not wishing to be bound by a particular theory, this could be due to a low substrate temperature, which may provide insufficient surface activation energy. The precursor injected in the afterglow region of the plasma can form a chemically active growth species, which is transported to the growing film surface to form Si—C(H) rich films. The spectrum of films deposited at a temperature below about 250° C. indicated that the film contains more Si-Et groups relative to films deposited at a temperature above about 250° C. The spectrum of samples deposited at a temperature above about 250° C. showed strong SiCN and SiN absorption with minimum contribution from the Si-Et groups. Though not wishing to be bound by a particular theory, this in turn can indicate that the increased substrate temperature activated the reaction between the adsorbed moieties. Samples subjected to a reactive gas not containing nitrogen and hydrogen showed no film growth. Though not wishing to be bound by a particular theory, this could signify that the nitrogen species in the afterglow may initiate the gas-phase reaction.

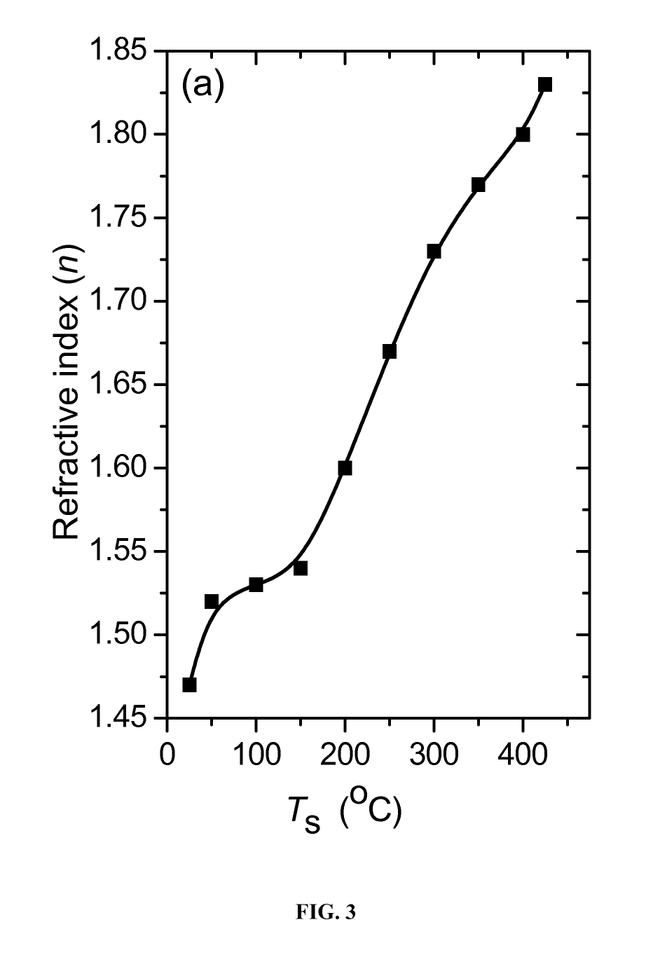

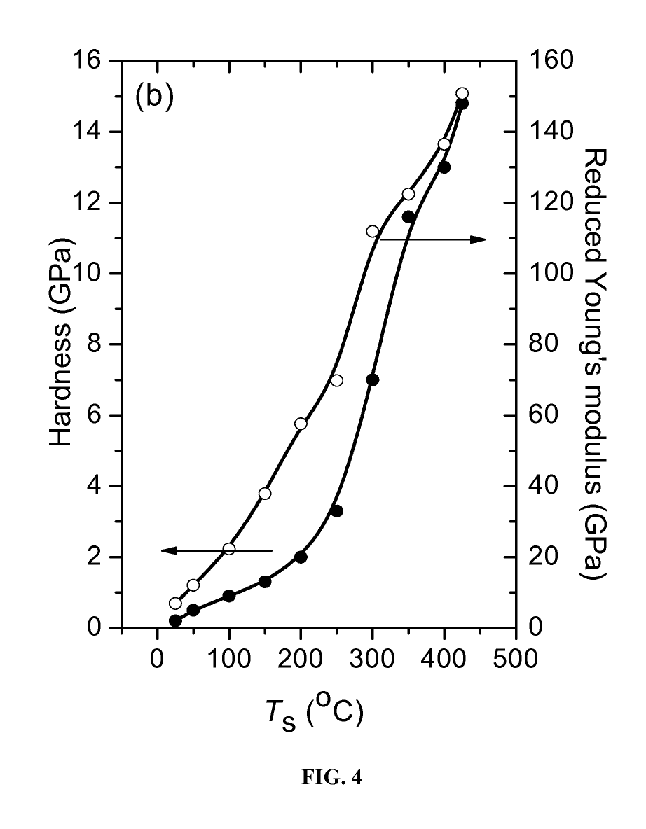

Referring to FIG. 3, the refractive index of the deposited film is plotted as a function of a substrate temperature. To derive the refractive index, ellipsometric parameters psi (ψ) and delta (Δ) were determined over the spectral range of about 300 nm to about 1700 nm in steps of about 10 nm. Referring to FIG. 4, the hardness and Young's modulus of the deposited film is plotted as a function of a substrate temperature. The Hardness (H) and reduced Young's modulus (Eᵣ) of the coatings were determined by depth sensitive indentation, using the TriboIndenter system by Hysitron Inc. (Eden Prairie, Minn.) equipped with a Berkovich pyramidal tip. The applied loads ranged from about 1 mN to about 5 mN. For each sample, the Hardness and reduced Young's modulus were obtained from an average of about 20 indentations. See W. C. Olivera & G. M. Pharr, An improved technique for determining hardness and elastic modulus using load and displacement sensing indentation experiments, 7 JOURNAL OF MATERIALS RESEARCH 1564-83 (1992) (incorporated by reference herein).

Table 1 summarizes the index of refraction, film thickness, and mechanical properties silicon-based coatings deposited at various plasma conditions and substrate temperatures. In general, the films have a refractive index lower than about 1.7 at substrate temperatures below about 300° C. Above about 300° C., the films show a refractive index higher than about 1.75 and up to about 1.86. Increase in the refractive index can help in decreasing the ARC layer thickness. Though not wishing to be bound by a particular theory, the reduced ARC thickness may in turn reduce the photon loss and the stress induced in the ARC layer.

TABLE 1
Refractive index, thickness, and mechanical properties of silicon-based coatings
deposited at various plasma conditions and substrate temperatures.

| Substrate | Gas flow | | | Film | | |
|---|---|---|---|---|---|---|
| temperature | (sccm) | | Refractive | thickness | Mechanical Properties | |
| (° C.) | N₂ | N₂—H₂ | index | (nm) | H (GPa) | E_{r (GPa)} |
| 250 | 0 | 0 | — | No film | | |
| 350 | 0 | 0 | — | No film | — | — |
| 250 | 500 | 0 | 1.64 | 195 | 2.3 (±0.1) | 57.6 (±1.5) |
| 300 | 500 | 0 | 1.73 | 144 | 7.0 (±0.3) | 111.9 (±6.2) |
| 350 | 500 | 0 | 1.71 | 170 | 11.6 (±0.3) | 122.4 (±3.1) |
| 400 | 500 | 0 | 1.74 | 164 | 13.0 (±0.3) | 136.5 (±3.4) |
| 425 | 500 | 0 | 1.82 | 201 | 14.6 (±0.4) | 150.8 (±2.8) |
| 250 | 495 | 100 | 1.63 | 97 | 3.4 (±0.1) | 94.5 (±3.9) |
| 300 | 495 | 100 | 1.63 | 83 | 10.0 (±0.2) | 128.3 (±3.7) |
| 350 | 495 | 100 | 1.69 | 86 | 12.0 (±0.3) | 127.6 (±0.3) |
| 400 | 495 | 100 | 1.70 | 95 | 13.5 (±1.2) | 148.2 (±14.8) |
| 425 | 495 | 100 | 1.72 | 117 | 14.0 (±0.7) | 146.5 (±7.3) |
| 250 | 305 | 200 | 1.61 | 63.1 | 6.7 (±0.1) | 125.6 (±3.0) |
| 300 | 305 | 200 | — | — | 12.3 (±0.2) | 139.2 (±2.6) |
| 350 | 305 | 200 | 1.78 | 62.1 | 14.2 (±0.3) | 148.2 (±2.3) |
| 400 | 305 | 200 | 1.80 | 83.4 | 15.8 (±0.3) | 157.3 (±3.6) |
| 425 | 305 | 200 | 1.80 | 83.1 | 16.7 (±0.4) | 156.4 (±3.0) |

The obtained films showed properties that are comparable with a-SiCN:H films obtained using vacuum PECVD. See, e.g., I. Blaszczyk-Lezak, A. M. Wrobel & D. M. Bielinski, Remote nitrogen microwave plasma chemical vapor deposition from a tetramethyldisilazane precursor. 2. Properties of deposited silicon carbonitride films, 497(1-2) THIN SOLID FILMS 35-41 (2006) (incorporated by reference herein). As shown in Table 1, the films deposited at substrate temperatures higher than about 300° C. tend to have a higher hardness (H). The mechanical properties of the disclosed AP-PECVD films are comparable to the coatings deposited with a vacuum-PECVD process using metal-organic precursors.

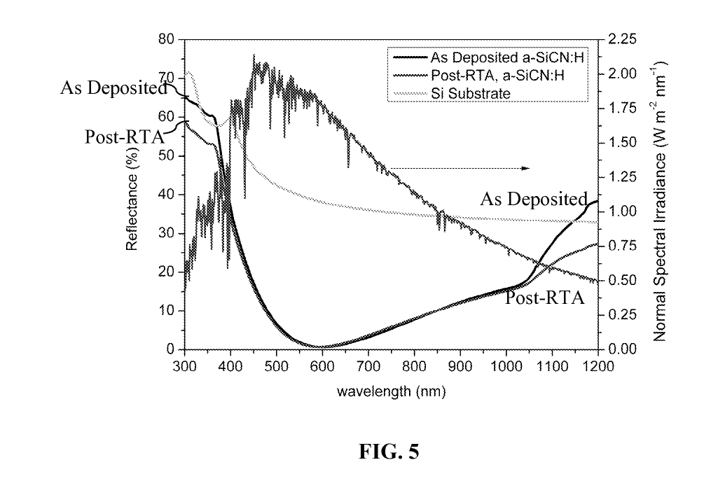

In order to determine the stability of the a-SiCN:H coatings for high temperature Ag metal firing process that is most commonly used in Si solar manufacturing processes, a-SiCN:H sample was subjected to a rapid thermal annealing (RTA) at about 700° C. for about 60 seconds. Relevant industrial standards may vary from about 750° C. to about 835° C. for about 1 second to a few seconds. The material properties measured before and after the rapid thermal annealing are summarized in the Table 2 & FIG. 5.

TABLE 2
a-SiCN:H properties before and after rapid thermal annealing
at about 700° C. for about 60 seconds.

| | | After rapid |
|---|---|---|
| | As | thermal |
| Properties | Deposited | annealing |
| Refractive index | 1.82 | 1.83 |
| Thickness(nm) | 201.4 | 200.8 |
| Hardness (Gpa) | 14.6 (± 0.2) | 17.0 (± 0.4) |
| Reduced Young's | 150.8 (± 2.8) | 151.1 (± 1.7) |
| modulus (GPa) | | |

FIG. 5 depicts the specular reflectance of a-SiCN:H that was subjected to rapid thermal annealing. Table 2 and FIG. 5 show that the rapid thermal annealing does not materially alter the material properties of a-SiCN:H, which is desirable for an anti-reflective coating in photo voltaics applications.

### Example 3

### SiCN:H Based Coatings for Anti-Reflection Coatings Varying Precursor Bubbler Flow

Antireflection coatings were made by reacting a triethylsilane precursor in a glove box by Surfx Technologies (Culver City, Calif.). The triethylsilane precursor was initially maintained in a bubbler, bubbling helium gas through the triethylsilane precursor at variable flow rates. Helium gas was supplied to the plasma source at about 30 liter/minute. The gases listed in Table 3 were used as the reactive gas at the respectively listed flow rates. The substrate was heated to about 260° C. The plasma head was held at a distance of about 4 mm to about 5 mm from the substrate, at a fixed plasma power of about 120 W to about 140 W. Depositions were carried out by moving the heated substrate under the plasma source in a serpentine motion at a velocity of about 0.6×10⁻² m·s⁻¹. Varying the precursor bubbler flow did not materially alter the refractive index of the antireflection coating.

### Example 4

### a-SiNₓ:H Thin Films for Anti-Reflective Coatings

a-SiNₓ:H thin films were fabricated using a cyclohexasilane (CHS) Si₆H₁₂ precursor such as is described in U.S. Pat. No. 5,942,637, incorporated by reference herein. The precursor was reacted with nitrogen in the plasma at atmospheric pressure, leading to the formation of a good SiNₓ:H thin films at a substrate temperature of about 200° C. to about 350° C.

The CHS precursor that was contained in the bubbler was heated to about 55° C. to increase the vapor pressure. Helium was used as the carrier gas at 0.9 liter/min through the bubbler. Helium gas was supplied to the plasma source at about 20 liters/minute. Nitrogen was used as the reactive gas at a flow rate of about 500 sccm. The substrate temperature was varied between about 100° C. to about 450° C. in the steps of 50° C. The remaining conditions were the same as in previous examples.

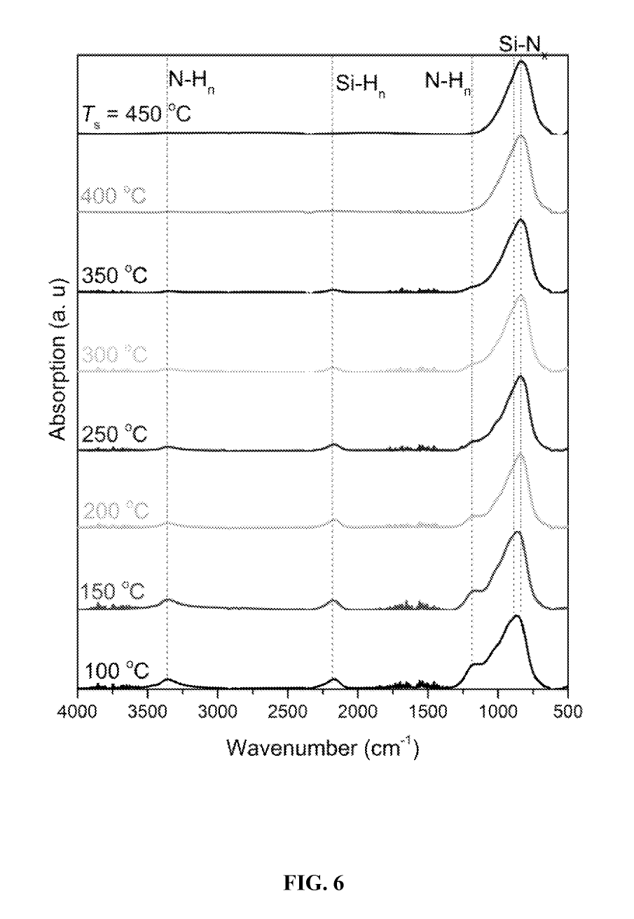

The a-SiNₓ:H thin films deposited at different substrate temperatures on intrinsic silicon substrates were examined using FTIR spectroscopy. The resulting spectra are depicted in FIG. 6. Surprisingly, films deposited at a low temperature of about 100° C. resulted in the formation of Si—N bond (˜840 cm⁻¹). Peaks corresponding to N—H and Si—H vibrations were also noted at 1160 cm⁻¹, 3360 cm⁻¹, and 2100 cm⁻¹. Increasing the substrate temperature resulted in a stronger intensity of the Si—N peak, and weaker Si—H and N—H peaks. At above about 250° C., good Si—N film formation was observed. Unlike in the standard vacuum PECVD or CVD process, good-quality a-SiNₓ:H films were obtained using CHS in AP-PECVD at substrate temperatures as low as about 250° C.

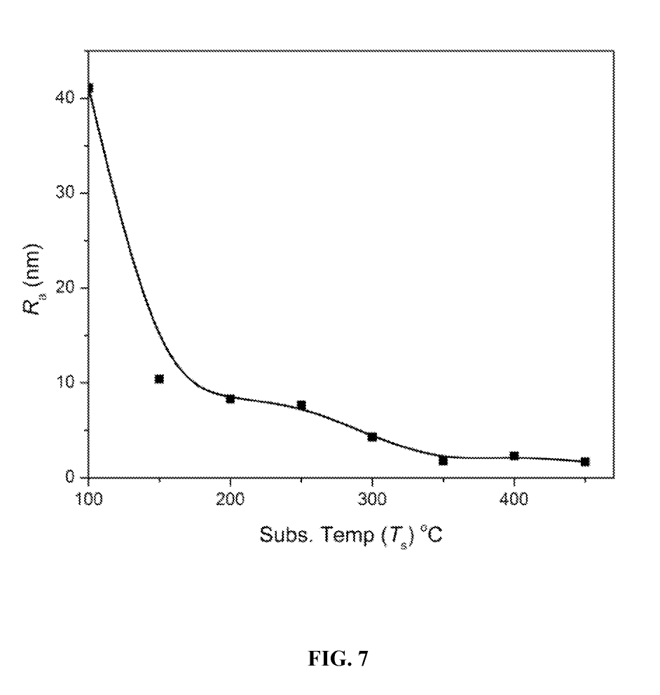

Surface morphology of the films was investigated using atomic force microscopy. FIG. 7 shows the surface roughness relative to substrate temperature. Increasing the substrate temperature resulted in a decrease in the surface roughness. A surface roughness of less than about 5 nm was observed for films synthesized at a substrate temperature above about 300° C. The observed surface roughness values are in agreement with values that were reported earlier using PECVD techniques.

TABLE 3
Refractive index, film thickness and density of a-SiNₓ:H films.

| | Refractive index | | Thickness | |
|---|---|---|---|---|
| Subs. Temp (° C.) | n | k | (nm) | Density (kg/m³) |
| 150 | 1.6 | 0.04 | 170 | 2.06 |
| 200 | 1.8 | 0.09 | 130 | — |
| 250 | 1.9 | 0.06 | 104 | 2.2 |
| 300 | 1.98 | 0.002 | 84 | 2.8 |
| 350 | 2.0 | 0.07 | 115 | 2.87 |
| 400 | 2.1 | 0.08 | 143 | — |
| 450 | 2.2 | 0.02 | 160 | 2.89 |

The refractive index, film thickness, and density of the obtained films are tabulated in Table 3. Films deposited at and above about 250° C. have a refractive index above about 1.9. Films with such refractive index values and a suitable thickness can provide excellent anti-reflective properties suitable for crystalline silicon solar cells. Increasing the substrate temperature between about 150° C. to about 300° C. additionally decreased the film thickness. Above about 300° C., an increase in thickness was observed. The measured film density of about 2.80 kg/m³ to about 2.89 kg/m³ was in agreement with a-SiNₓ:H deposited using other vacuum-based techniques.

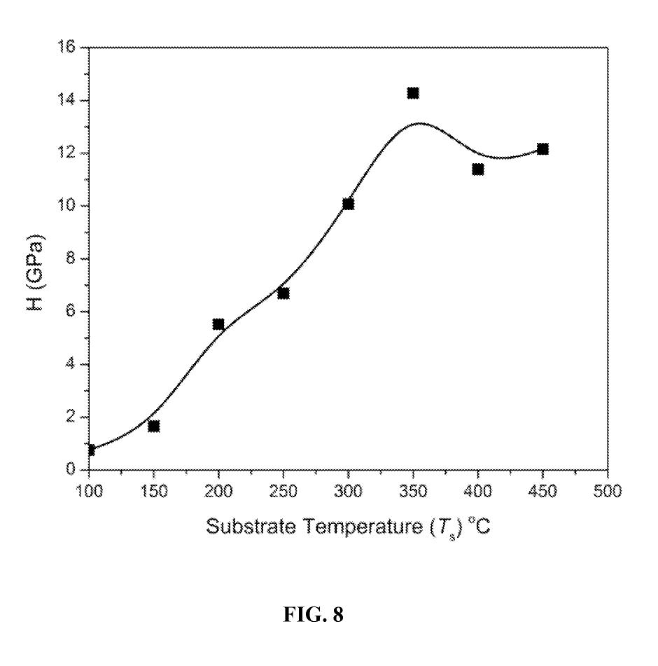

Mechanical properties such as hardness and Young's modulus of the coatings were determined using a nanoindenter. FIG. 8 shows hardness (H) values of the coatings as a function of the substrate temperature. Films deposited above about 300° C. showed hardness greater than about 10 GPa, confirming the formation of a strong Si—N bond.

It is understood that the disclosure may embody other specific forms without departing from the spirit or central characteristics thereof. The disclosure of aspects and embodiments, therefore, are to be considered in all respects as illustrative and not restrictive, and the claims are not to be limited to the details given herein. Accordingly, while specific embodiments have been illustrated and described, numerous modifications come to mind without significantly departing from the spirit of the invention and the scope of protection is only limited by the scope of the accompanying claims.

1. A process for forming a silicon-containing film on a substrate, the process comprising:
providing a substrate;
providing a precursor comprising silicon; and
reacting the precursor with a gas comprising nitrogen (N₂) in a low-temperature plasma at atmospheric pressure, wherein the products of the reacting form a film on the substrate.

2. The process of claim 1 performed in an environment that is substantially free of oxygen.

3. The process of claim 1, wherein said substrate comprises silicon.

4. The process of claim 1, wherein the precursor is a liquid at room temperature.

5. The process of claim 1, wherein the precursor is selected from the group consisting of silane, silazane, silicon-carbide, silicon-nitride, and silicon carbonitride.

6. The process of claim 5, wherein the precursor is selected from the group consisting of cyclochexasilane, triethylsilane, dimethylsilane, trimethylsilane, tetramethylsilane, diethylsilane, tetraethylsilane, dipropylsilane, tripropylsilane, tetrapropylsilane, silicon-carbide, silicon-nitride, silicon carbonitride, bis(tertiarybutylamino)silane, 1,1,3,3-tetramethyldisilazane, hexamethylcyclotrisilazane, tris(dimethylamino)methylsilane, and bis(dimethylamino)methylsilane.

7. The process of claim 1, wherein the substrate is maintained at a temperature from about 25° C. to about 450° C.

8. The process of claim 1, wherein an RF power from about 40 W to about 150 W is applied to excite the plasma.

9. The process of claims 1, wherein the gas comprises nitrogen with 0% to about 5% hydrogen by volume.

10. The process of claim 1, wherein the gas is substantially free of ammonia.

11. The process of claim 1, wherein the precursor includes cyclochexasilane and the gas comprises 0% to about 5% ammonia by volume.

12. An antireflection coating made by a process comprising:
reacting a silicon-containing precursor with a gas comprising nitrogen (N₂) in a low-temperature plasma at atmospheric pressure,
wherein the antireflection coating has a refractive index of about 1.5 to about 2.2.

13. The coating of claim 12, wherein the coating comprises at least one of silicon nitride and silicon carbonitride.

14. The coating of claim 12, wherein the coating is substantially free of silicon oxide.

15. The coating of claim 12, wherein the gas is substantially free of ammonia.

16. The coating of claim 12, wherein the precursor includes cyclochexasilane and the gas comprises 0% to about 5% ammonia by volume.

17. The coating of claim 12, wherein the coating has a hardness of about 7 GPa to about 17 GPa.

18. An article having a surface comprising an antireflection coating, wherein the coating made by a process comprising:
reacting a silicon-containing precursor with a gas comprising nitrogen (N₂) in a low-temperature plasma at atmospheric pressure,
wherein the coating has a refractive index of about 1.5 to about 2.2.

19. The article of claim 18, wherein the coating comprises at least one of silicon nitride and silicon carbonitride.

20. The article of claim 18, wherein the coating is substantially free of silicon oxide.

21. The article of claim 18, wherein the gas is substantially free of ammonia.

22. The article of claim 18, wherein the precursor includes cyclochexasilane and the gas comprises 0% to about 5% ammonia by volume.

23. The article claim 18, wherein the coating has a hardness of about 7 GPa to about 17 GPa.
